(19) United States
(12) Patent Application Publication
(10) Pub. No.: US 2002/0132490 A1
(43) Pub. Date: Sep. 19, 2002

(54) Microstructure having a membrane and a wedge beneath and methods for manufacture of same

(76) Inventor: Lieyi Sheng, Brussels (BE)

Correspondence Address: SLATER & MATSIL, L.L.P., 17950 PRESTON RD, SUITE 1000, DALLAS, TX, 75252-5793, US

(21) Appl. No.: 09/811,289

(22) Filed: Mar. 16, 2001

(51) Int. Cl. H01L 21/461

(52) U.S. Cl. 438/733

(57) ABSTRACT

A microstructure comprising a spider-like membrane and a wedge beneath is designed and fabricated on the silicon substrate using common IC techniques and silicon anisotropic etching process. The wedge beneath can contact the membrane to provide mechanical support, or form a narrow gap with the membrane to realize several device functions. The microstructures are adaptable for many applications and can be easily implemented into standard CMOS chips.

### FIELD OF THE INVENTION

The present invention is related to microstructures and methods for manufacturing same. In particular, the present invention relates to semiconductor processing methods for manufacturing a microstructure having a flexible membrane formed atop a wedge structure, and applications for same.

### BACKGROUND OF THE INVENTION

Semiconductor micromachining techniques have been developed for more than two decades, with the trend for micromachined devices now moving in the direction of silicon based MicroElectroMechanical Systems (MEMS) because of the rapid development of silicon industry. Microstructures having suspended membranes have been widely used for various device functions. Using semiconductor micromachining techniques, structures having the membrane isolated from the substrate are possible, allowing for improved thermal characteristics as well as other device characteristics.

Suspended microstructures generally fall into two categories: spider-type and membrane-type. Generally, the spider-like microstructure is more popular because of its technical simplicity and compatibility with standard CMOS processing. For making such microstructures, the silicon micromachining process is carried out from the front side of a wafer, so commonly used single-side polished wafers can be used and no extra equipment for double-side photolithography is needed. Moreover, because such microstructures allow for front-side micromachining, die size enlargement effects can be minimized, allowing for higher device density. Based on the spider-like microstructures, various kinds of micro-devices, such as gas sensors, gas flow sensors and pressure sensors, as well as thermal radiation emitters, can be miniaturized, or even made possible.

A shortcoming of prior art microstructures is their lack of robustness. Because the suspended portion of all these microstructures is only mechanically supported by some very delicate micro-bridges, their structural rigidity is quite poor. This shortcoming restricts the practicality of such structures in harsh environments. The structural instability also affects the electrical and performance stability of the device characteristics. Furthermore, certain devices such as integrated gas sensors, require that specific functional thin- or thick-films are deposited and patterned after the suspended microstructure is formed. Typical prior art spider-like microstructures are mechanically too weak for further process, such as photolithographic steps, to be carried out, however, without damaging or destroying the microstructure. As such, many desirable devices, such as integrated gas sensors based on spider-like microstructures, are not commercially practical because of the above described shortcomings.

For some other semiconductor devices, such as field emission devices, high electric fields are needed. For such devices, the suspended membrane should be kept away from the underlying silicon structure by a very small distance (e.g., <10 μm) in order to have a sufficiently high electric field on the underlying silicon structure. As is known in the art, the smaller the separation, the easier the needed electric field can be obtained. When the electric field is high enough (>10⁷ V/cm), electrons can be emitted from the silicon structure. Field emission diodes and triodes have been fabricated by using very small separations, and consequently low turn-on voltages can be achieved. Achieving a microstructure with a sufficiently small separation, and having necessary structural robustness and being compatible with conventional semiconductor processes, however, has proved problematic in the art.

These and other shortcomings in the prior art can be overcome by employing the present invention, which is described herein with reference to several preferred embodiments.

### SUMMARY OF THE INVENTION

In a first aspect, the invention provides for a method of forming a microstructure having a membrane overlying a wedge shaped element. The method comprises forming a first layer over a semiconductor surface substrate and patterning the first layer to form openings to the underlying semiconductor substrate, whereby the openings define a membrane structure a plurality of microbridges connecting the membrane structure and the first layer. The method further includes anisotropically etching the semiconductor substrate through the openings to form a wedge shaped structure under the membrane, whereby the wedge shaped structure has a first and second angular surface, the angular surface lying along a crystalline plane of the semiconductor substrate.

In another aspect, the invention provides for a microstructure comprising a membrane structure formed in a first layer overlying a substrate, being defined by a series of openings in the first layer and comprising a primary region and a plurality of microbridges interconnecting the primary region and the remainder of the first layer, and a wedge shaped element beneath the membrane structure. The wedge shaped element is formed in the substrate and has a substantially horizontal top surface and a first and second side surface, the first and second side surfaces lying along a crystalline plane of the substrate.

A first advantage of the preferred embodiments of the present invention is to provide a spider-like membrane, which is made by using the commonly used silicon anisotropic etching process, and during the same process a silicon supporting wedge is simultaneously formed underneath the suspended portion.

A further advantage of the preferred embodiments of the present invention is to integrate several electrical components into the micro-structures to develop the membranes as functional platforms by using the conventional IC technology. Prior to the substrate anisotropic etching process, stacked layers, such as those make of metals, semiconductors and dielectrics, can be progressively formed and patterned on the first layer.

A still further advantage of the preferred embodiments is to allow for removal of one or several layers of the formed membrane to form a fully suspended new membrane. The removed layer or layers are used as a sacrificial layer, and the formed gap between the fully suspended membrane and the wedge can be mainly controlled by the total thickness of the removed layers.

Yet another advantage of the preferred embodiments is to design and make the front-end fabrication of the spider-like microstructures by standard CMOS processing. The microstructure is finally formed by using the silicon anisotropic etch process.

These and other objects will be made more clear in connection with the following detailed description of the drawings identified below.

### BRIEF DESCRIPTION OF THE DRAWINGS

FIGS. 1a and 1b are plan view and cross sectional view, respectively, of a first preferred embodiment microstructure;

FIG. 1c illustrates a preferred embodiment photomask pattern for forming exemplary microstructures;

FIG. 2 is the top view of the commonly used (100) silicon wafer with the (110) primary flat;

FIGS. 3a through 3d show the process of making a first preferred embodiment microstructure with a single-layer membrane and a supporting wedge beneath;

FIG. 4 is a cross sectional view of a second preferred embodiment microstructure having a multi-layer membrane;

FIG. 5 is a cross sectional view of a third preferred embodiment microstructure having embedded polysilicon or metal thermoresistors in a wedge-supported membrane for thermally based micro sensors and micro actuators;

FIG. 6 is a cross sectional view of a preferred embodiment microstructure with embedded metal lines between the several dielectric layers in a wedge-supported membrane for inductor applications;

FIG. 7 illustrates a preferred embodiment microstructure with a fully suspended membrane over a silicon wedge;

FIGS. 8a and 8b show the process of making the preferred embodiment microstructure with a fully suspended membrane over a silicon wedge; and

FIGS. 9a and 9b show the process of making an alternative preferred embodiment microstructure on standard CMOS chips by using post-CMOS silicon anisotropic etch process.

### DESCRIPTION OF PREFERRED EMBODIMENTS

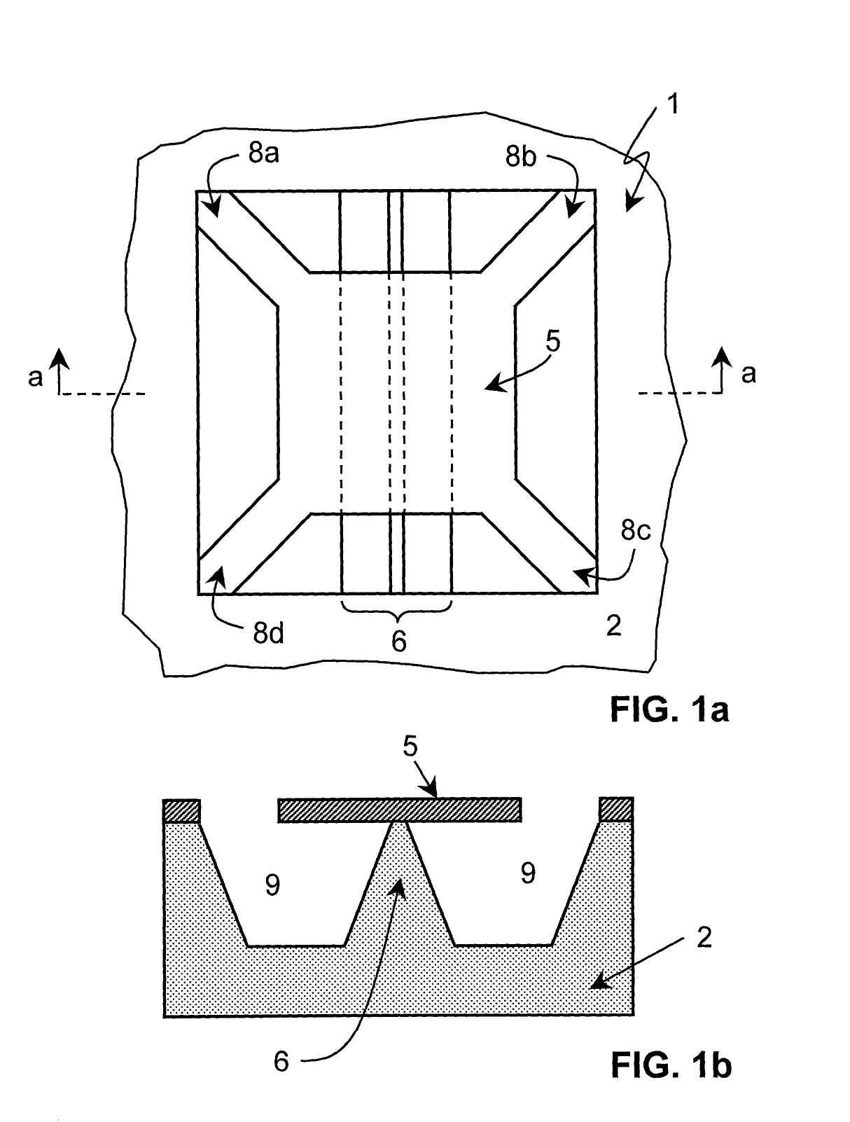

FIGS. 1a and 1b illustrate a first preferred embodiment microstructure 1 formed in a top surface of a silicon substrate 2. The structure includes a spider-type membrane 5 formed over a wedge shaped underlying structure 6. The membrane is supported by four micro-bridges 8a-8d. The membrane 5 is shown in plan view in FIG. 1a and the shape of the underlying structure is best illustrated in cross-sectional view FIG. 1b taken along the axis indicated by dotted line aa in FIG. 1a. FIG. 1c illustrates a portion of a preferred photomask 10 showing the opening areas used during the steps of etching the substrate 2 to form the patterns illustrated in FIGS. 1a and 1b. Further details of the manufacturing of microstructure 1 will be provided in the following description.

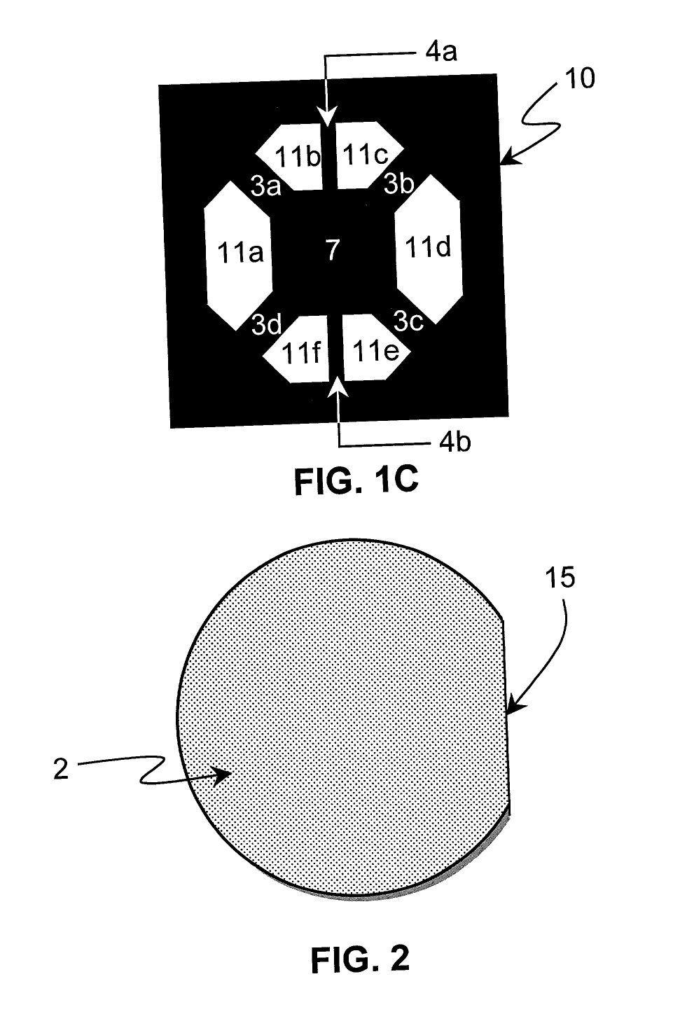

As shown in FIG. 1c, six polygonal windows or openings 11a through 11f are arranged about the periphery of and define a rectangular area 7. In the preferred embodiments, microstructure 1 is formed on a silicon substrate, having a (100) crystal orientation on surface, as is commonly used in semiconductor manufacturing processes. Rectangular region 7 and regions 3a, 3b, 3c, and 3d, mask the underlying surface, thus forming membrane 5 and micro-bridges 8a-8d, as will be discussed in more detail below. Vertical regions 4a and 4b, which are defined by windows 11b and 11c and by windows 11e and 11f, respectively, should be aligned to the intersection of the {11} crystallographic plane and the wafer surface plane. It is noted that standard CMOS foundries use round (100) silicon wafers for standard CMOS processing and the round wafers are normally supplied with the primary flat 15 that is oriented along the <110> direction, as shown in FIG. 2. In this case, the vertical regions 4a and 4b should be parallelly or vertically aligned to the primary flat 15 of the (100) silicon wafer 2, in order to take advantage of the selective etching properties of anisotropic etchants, as described more fully below.

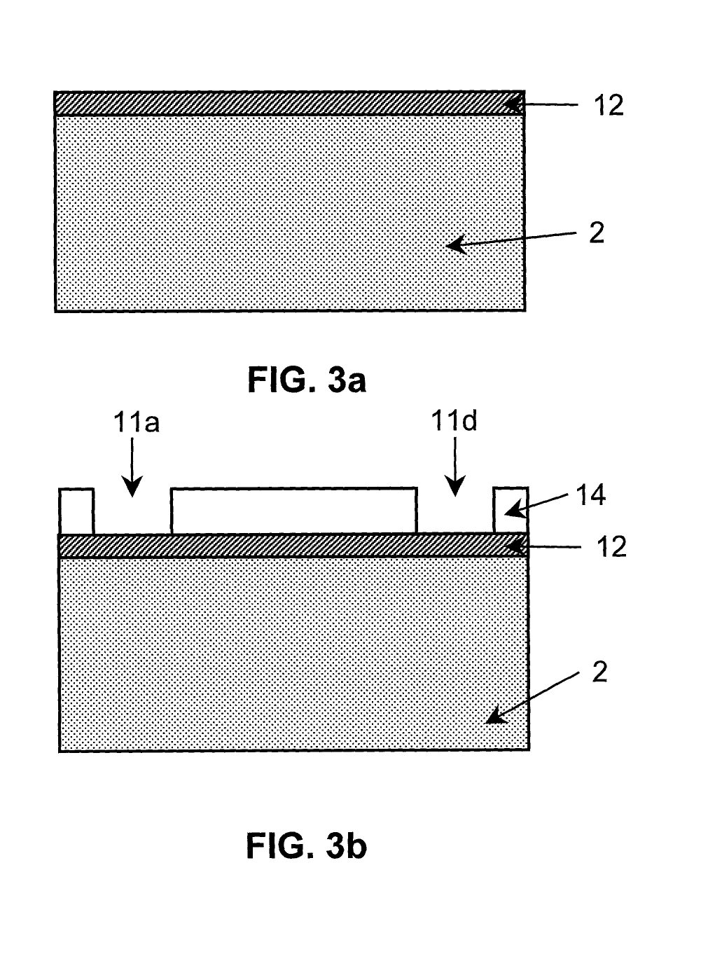

FIGS. 3a through 3d illustrate the basic manufacturing process for exemplary microstructure 1. Dielectric layer 12 is formed atop silicon substrate 2, as shown in FIG. 3a. In the preferred embodiments, dielectric layer is a thermally grown silicon dioxide of between approximately 0.2 to 2 microns in thickness. Dielectric layer could alternatively be a deposited silicon dioxide, or some other dielectric layer such as silicon nitride or other dielectric material compatible with standard CMOS processes.

Photoresist layer 14 is then deposited over dielectric layer 12 and patterned with photomask 10 using well known photolithography techniques, leaving a pattern defined by windows 11a through 11f. Windows 11a and 11d are illustrated in the cross sectional view of FIG. 3b. Dielectric layer 12 is then etched through the windows in photomask layer 14 to form openings 11a through 11f in dielectric layer 12. Many well known techniques exist in the art for etching dielectric layer 12, including well known wet or dry etch processes. After etching dielectric layer 12, photomask layer 14 is removed, leaving dielectric layer 12 patterned with openings 11a through 11f. Openings 11a and 11d are shown in the cross sectional region illustrated in FIG. 3c.

Silicon substrate 2 is next anisotropically etched via openings 11a through 11f that have been formed in dielectric layer 12. The basis of anisotropy is that the etching rate in the <100> direction is significantly higher than in the <111> direction. Many silicon etchants, such as KOH and TMAH, can be used for this purpose. With the layout design in FIG. 1c, portions of silicon substrate 2 will be etched away, leaving two etch pits 9 with their sidewalls along the etch resistant {111} planes at an angle of 54.74° to the surface plane of the (100) silicon wafers, as illustrated in FIG. 3d. The residual silicon between the two neighboring sidewalls forms the silicon wedge 6 underneath the membrane 5. The top size of the silicon wedge 6 is controlled by the designed width of the vertical regions 4a and 4b of FIG. 1c. The size of the membrane 5 is determined by the rectangular area 7 of photomask 10 (as shown in FIG. 1c), which is surrounded by the polygonal openings 11a through 11f. The membrane 5 is also mechanically supported by the four suspended micro-bridges 8a-8d, and the widths of these micro-bridges are determined by the four diagonal regions 3a through 3d shown in FIG. 1c. Using standard anisotropic etch processes, wedge 6 can be made as narrow of 0.1 um. In other applications, a wider top, up to several microns wide at the top, may be employed by selecting the sizes of the openings in the photomask 10.

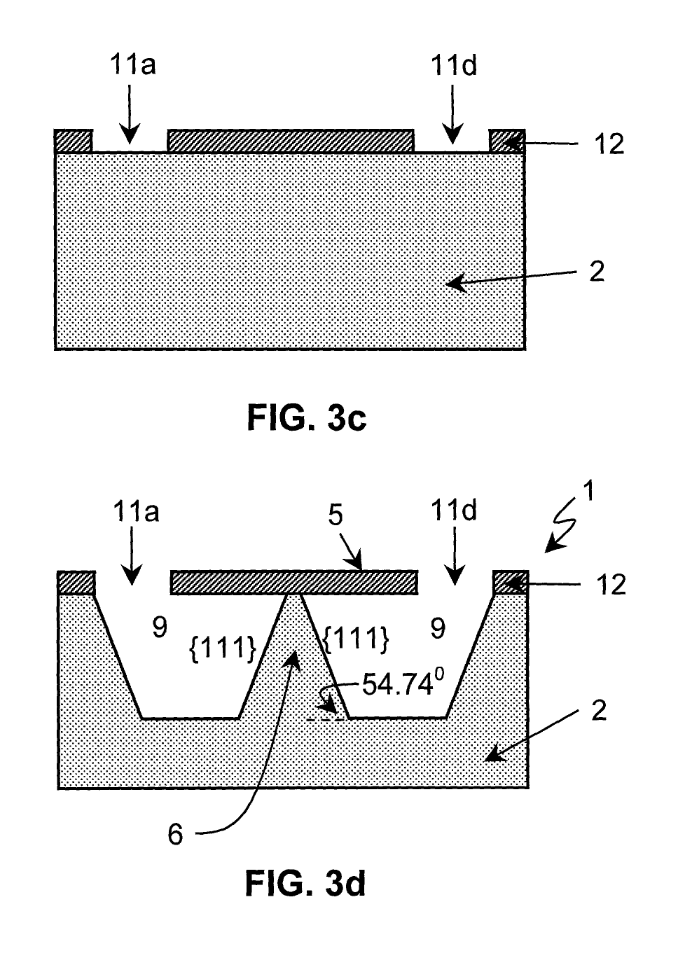

Prior to the silicon anisotropic etch process, layers can be deposited and patterned above the silicon substrate 2 to form various structures and devices, as illustrated with reference to FIGS. 4 through 9 and the following description of alternative preferred embodiments. Throughout the description of the alternative embodiments, similar structures and layers will be given common reference numerals.

FIG. 4 provides a cross-section view of an alternative embodiment microstructure having a multilayer membrane 16 and a supporting wedge 6 beneath. Multilayer membrane 16 is comprised of three sub-layers 18, 20, and 22. These three sub-layers are preferably formed of common semiconductor process materials, such as well polysilicon, silicon oxide, silicon nitride, or the like. In some applications, one or more of the sub-layers may be formed of a conductor material, such as aluminum, gold, copper, titanium, tungsten, tungsten silicide, titanium silicide, or other well known conductor materials of combinations of materials. Depending upon the application, the sub-layers may range from hundredths of a micron to several microns in thickness. One skilled in the art will also recognize that certain design constraints such as thermal expansion matching, and adhesion will restrict the selection of materials for the sub-layers to ensure compatibility. Their thickness can range from 0.01 to some microns. The advantage of using multi sub-layers is that we can improve the structural rigidity, layer-to-layer adhesion or thermal match. Preferably sub-layers 18, 20, and 22 are formed using well known deposition techniques (sputtering, evaporation, LPCVD, PECDV, and the like) and then the layers are patterned using photomask 10 and etched. Depending upon the characteristics of the various sub-layers, one or more etch steps may be necessary to form the membrane 5 and micro-bridges 8a through 8d.

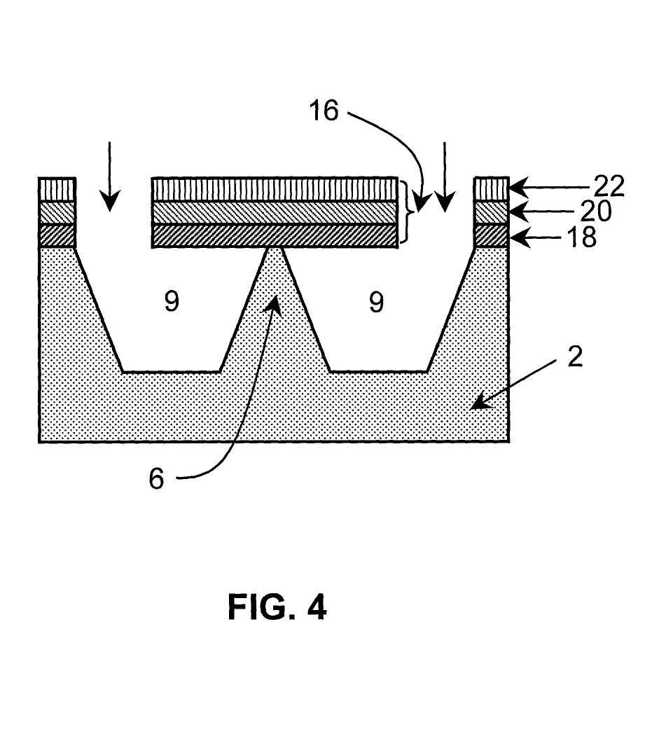

FIG. 5 illustrates another preferred embodiment microstructure having embedded polysilicon or metal thermoresistors in the membrane. The resulting structure can be used for thermally based microsensors and microactuators. In the preferred embodiment illustrated in FIG. 5, layers 17, 18 and 19 are dielectric layers. After the first layer 17 is formed on the substrate 2 by using deposition or thermal oxidation, a layer of poly-Si or metal is deposited and (in the case of polysilicon) doped. The layer is then patterned to form the layer 21 with a serpentine pattern as the heating element for thermal micro-sensors or actuators. The dielectric layers 18 and 19 are then formed and patterned atop to cover the serpentine poly-Si or metal thermoresistor 21. Layers 17, 18, and 19 are then covered with a layer of photoresist, which is patterned using photomask 10, and the layers are etched to form openings 20 shown in FIG. 5. Finally, substrate 2 is etched through the openings to form the membrane supported by micro-bridges 8a through 8d and by wedge support 6, as discussed above.

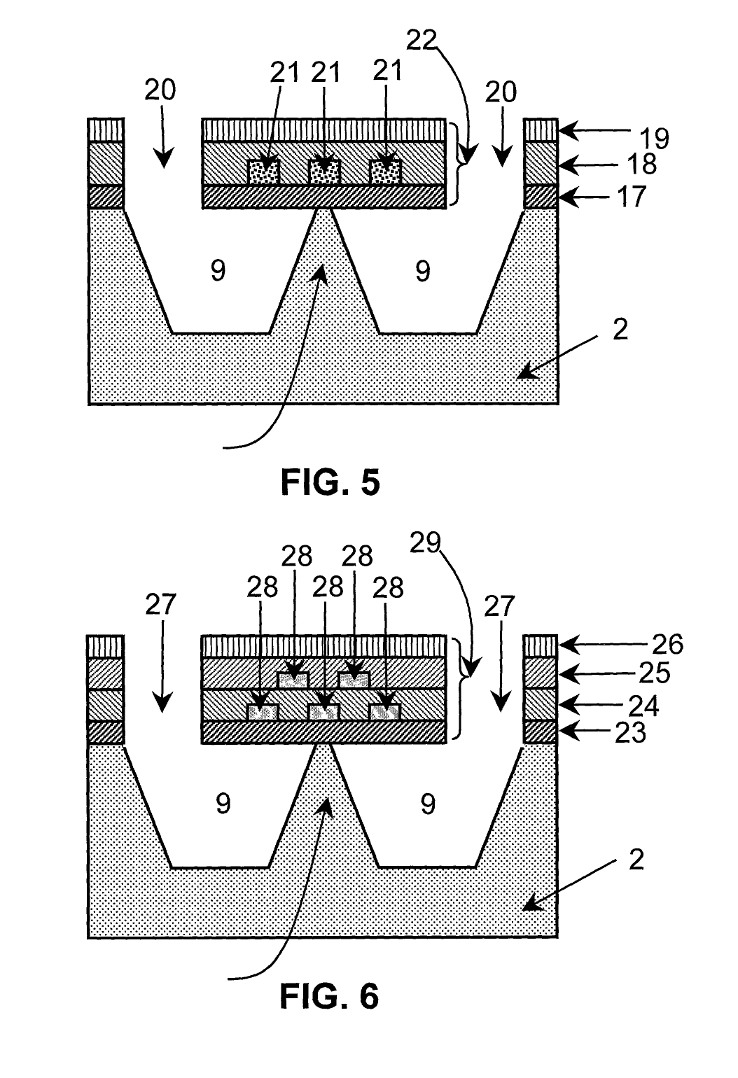

FIG. 6 illustrates another preferred embodiment microstructure having embedded metal lines between several dielectric layers in the membrane. The resulting microstructure can be used for coil- or spiral-type RF transformers. After the first dielectric layer 23 is formed on the substrate 2, a layer of metal is deposited and then patterned to form the coil-like metal pattern 28 on the layer 23. Dielectric layer 24 is deposited atop metal pattern 28 and insulating layer 23. A second metal layer is deposited and patterned, forming an additional metal pattern layer 28 on top of dielectric layer 24 (which acts as an inter-level insulating layer). Dielectric layers 25 and 26 are formed atop this second metal pattern. Openings 27 are then formed in the dielectric layers to form membrane 29 and underlying substrate 2 is patterned to form wedge support 6, as described above.

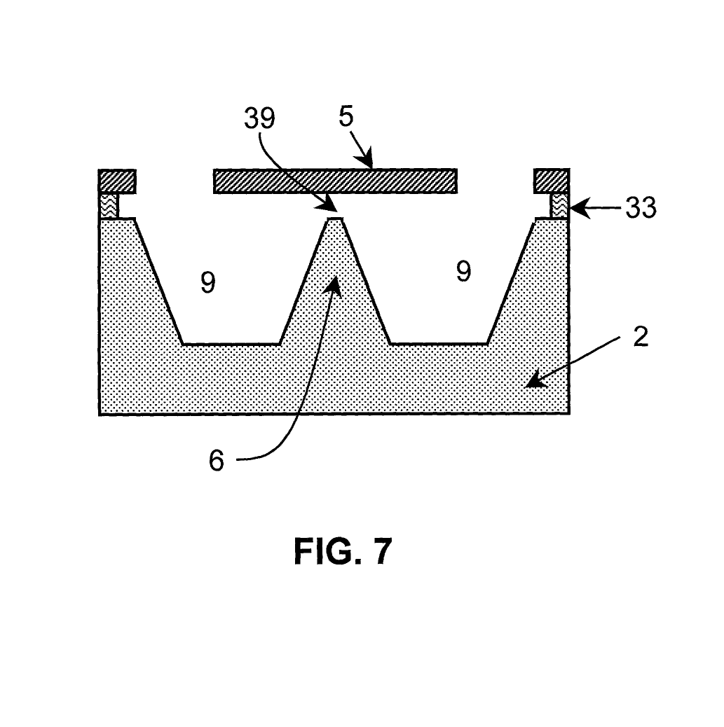

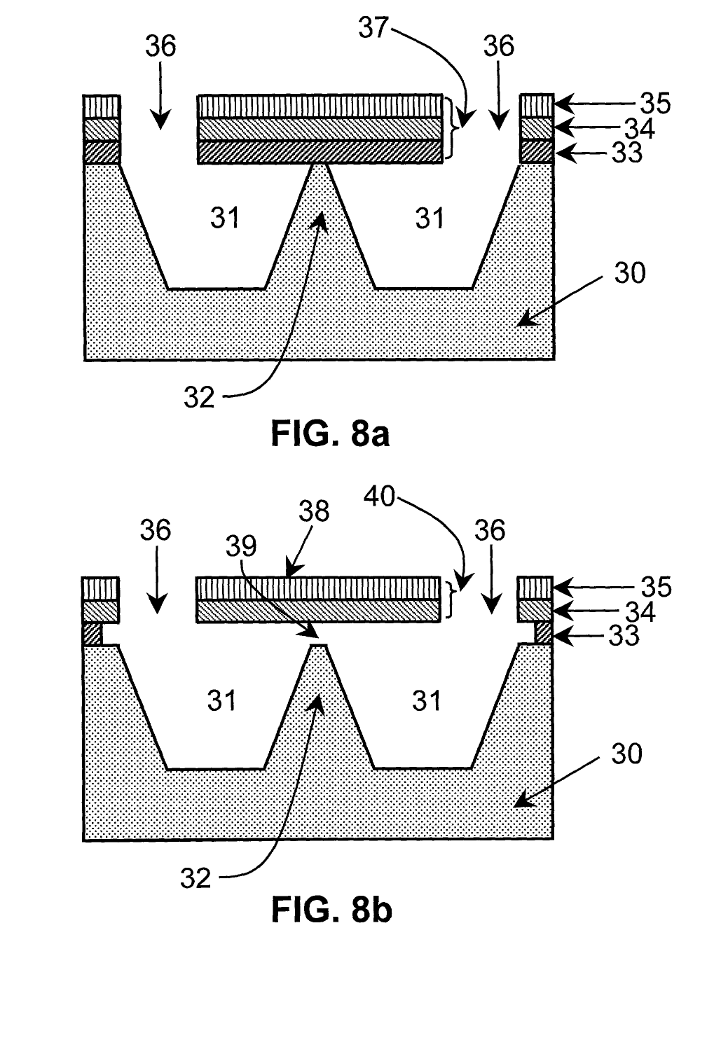

In yet another embodiment, an exemplary microstructure can be fabricated having a membrane 5 that is fully supported by micro-bridges 8a through 8d and having a gap 39 between membrane 5 and underlying wedge structure 6, as shown in FIG. 7. Such a microstructure would have particular applicability as, e.g., a field emission diode. FIGS. 8a and 8b show the process of making the microstructure with a fully suspended membrane over a silicon wedge with a small gap between them by employing a sacrificial layer 33.

As illustrated in FIG. 8a, sacrificial layer 33 is first formed atop substrate 2. Sacrificial layer 33 is preferably a thermally grown or deposited silicon dioxide layer. Layers 34 and 35 are then formed atop sacrificial layer 33. Preferably layers 34 and 35 are formed of polysilicon or metal—and have a different etch chemistry than that of sacrificial layer 33. The layers 33, 34, and 35 are patterned and etched to form openings 36 as described above, and the underlying substrate 2 is anisotropically etched to form wedge 32. After the silicon anisotropic etching process, the portion of the layer 33 between the silicon wedge 32 and the layers 34 and 35 is etched away thus forming gap 39 between the fully suspended membrane 40 and the silicon wedge 32. The thickness of gap 39 will depend upon the thickness of sacrificial layer 33 and can range from one hundredth of a micron to several microns. In an alternative embodiment, sacrificial layer 33 is formed of polysilicon and can be etched away concurrently with the anisotropic etch of underlying substrate 2.

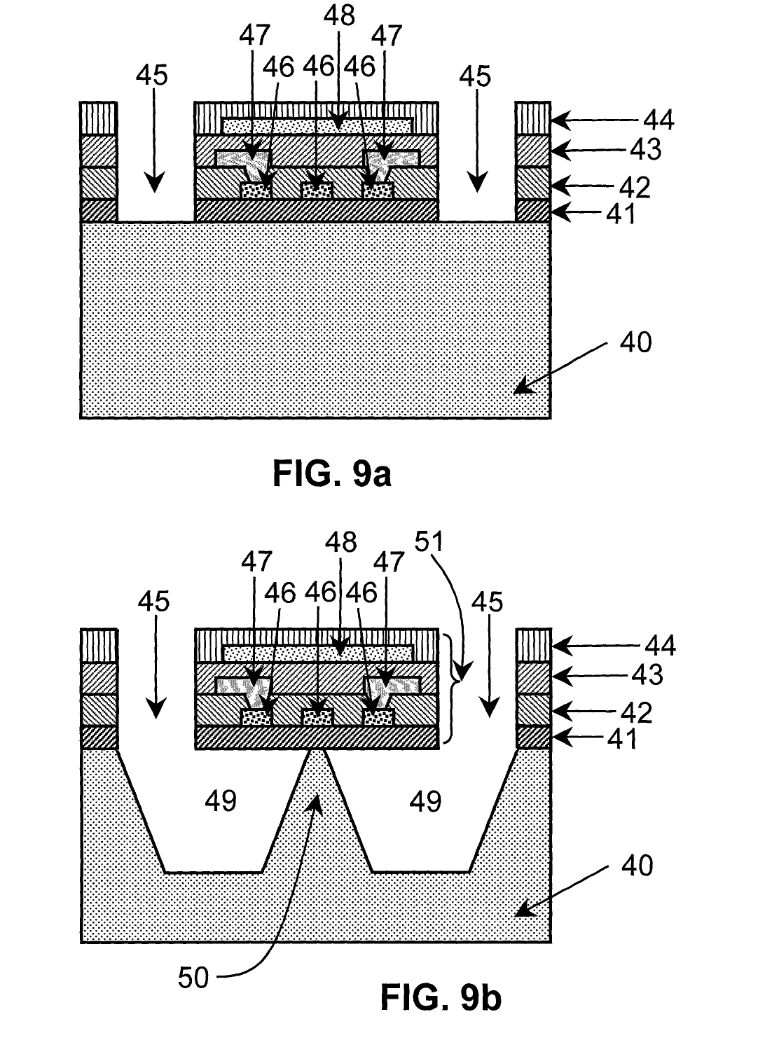

The front-end fabrication of the preferred embodiment microstructures can be made to be fully compatible with the standard CMOS processing. For instance, FIG. 9a shows the cross-section view of the stacked dielectric layers 41-43, the final passivation layer (e.g., silicon nitride) 44 and buried elements 46, 47, and 48 (such as metal patterns and polysilicon resistors) formed within the dielectric layers, as discussed above. All the various layers can be fabricated on the (100) silicon surface of a silicon substrate 2, which can be processed in standard CMOS foundries. The openings 45 are used as the post-CMOS silicon anisotropic etching windows to form the micro-structure with the functional wedge-supported membrane 51, as shown in FIG. 9b. The illustrated preferred embodiment is implemented as standard CMOS chips in which functional devices can be realized by combining the standard CMOS technology (such as industrial twin-well, double poly and double metal process) and the post-CMOS anisotropic etching step. An active area (50×50 μm²), which is also related with the area of the wedge-supported membrane 51, is heated up by a poly-Si ringlike resistor (poly-Si-1 in the CMOS chip, 0.42 μm in thickness), and an inner serpentine resistor is used to monitor the temperature. Both resistors have a line width of 2 μm. Dielectric oxide layers 41, 42 and 43 are 0.52 μm, 0.65 μm and 1.0 μm in thickness, respectively. A square metal plate 48 (metalization-2 in CMOS processing, 1 μm in thickness) covers the active area, to accumulate heat and improve the temperature uniformity. Finally, the devices were covered with a 1-μm-thick nitride passivation layer 44.

It will, of course, be understood that there could be several modifications of the present invention in its various aspects. For example, the pentagonal or hexagonal openings 1 of the layout in FIG. 1 may be simplified to triangular or quadrilateral openings. The silicon substrate may be replaced by other semiconductor substrates, such as GaAs substrate, and the like. As such, the scope of the invention should not be limited by the particular embodiments herein described but should be only defined by the appended claims and equivalents thereof.

I claim:

1. A method of forming a microstructure, the microstructure having a membrane overlying a wedge shaped element, the method comprising:
forming a first layer over a semiconductor surface substrate;
patterning the first layer to form openings to the underlying semiconductor substrate, whereby the openings define a membrane structure a plurality of microbridges connecting the membrane structure and the first layer; and
anisotropically etching the semiconductor substrate through the openings to form a wedge shaped structure under the membrane, whereby the wedge shaped structure has a first and second angular surface, the angular surface lying along a crystalline plane of the semiconductor substrate.

2. The method of claim 1 further comprising:
forming a second layer over the first layer, and patterning the first and second layers simultaneously.

3. The method of claim 1 further comprising:
forming a second layer over the first layer, and patterning the first and second layers independently.

4. The method of claim 1 wherein said first layer is a dielectric.

5. The method of claim 4 wherein said first layer is silicon oxide.

6. The method of claim 1 wherein said crystalline plane is the <111> plane.

7. The method of claim 1 wherein said semiconductor substrate is silicon.

8. The method of claim 1 wherein said plurality of microbridges comprises four microbridges.

9. The method of claim 1 further comprising:
forming a sacrificial layer on the semiconductor substrate surface prior to forming the first layer;
patterning the first layer and the sacrificial layer simultaneously or independently;
etching away the sacrificial layer subsequent to anisotropically etching the semiconductor substrate to form a gap between the membrane structure and the wedge shaped structure.

10. The method of claim 9 wherein the sacrificial layer is formed of silicon oxide.

11. A microstructure comprising:
a membrane structure formed in a first layer, the first layer overlying a substrate, the membrane structure being defined by a series of openings in the first layer and comprising a primary region and a plurality of microbridges interconnecting the primary region and the remainder of the first layer; and
a wedge shaped element beneath the membrane structure, the wedge shaped element being formed in the substrate and having a substantially horizontal top surface and a first and second side surface, the first and second side surfaces lying along a crystalline plane of the substrate.

12. The microstructure of claim 11 wherein the membrane structure rests on the wedge shaped element.

13. The microstructure of claim 11 wherein the membrane structure is separated from the wedge shaped element by a gap.

14. The microstructure of claim 11 wherein the membrane structure is comprised of a dielectric material.

15. The microstructure of claim 11 wherein the membrane structure is comprised of several layers.

16. The microstructure of claim 11 further comprising:
a patterned resistive element embedded within the membrane structure.

16. The microstructure of claim 11 further comprising:
a patterned conductive element embedded within the membrane structure.
